(19) United States
(12) Patent Application Publication
(10) Pub. No.: US 2012/0187986 A1
(43) Pub. Date: Jul. 26, 2012

(54) LATCH CIRCUIT, CDR CIRCUIT, AND RECEIVER

(75) Inventors: Daisuke Hamano, Hachioji (JP); Tatsunori Usugi, Inagi (JP)

(73) Assignee: HITACHI, LTD.

(21) Appl. No.: 13/349,195

(22) Filed: Jan. 12, 2012

(30) Foreign Application Priority Data
Jan. 20, 2011 (JP) 2011-009362

(51) Int. Cl. H03L 7/06; H03K 3/356

(52) U.S. Cl. 327/156; 327/208

(57) ABSTRACT

A receiving circuit that consumes less electric power is provided. The present invention provides a latch circuit that latches a differential signal by interrupting an electric current generated by a differential input using a corresponding differential output when the differential signal is differentially amplified. By using the latch circuit, transmitted data can be received even if the voltage difference of the differential signal components of the received signal is small. As a result, the number of amplifiers can be reduced, thereby enabling the power consumption of the receiver to be reduced.

### CLAIM OF PRIORITY

The present application claims priority from Japanese patent application JP 2011-009362 filed on Jan. 20, 2011, the content of which is hereby incorporated by reference into this application.

### FIELD OF THE INVENTION

The present invention relates to a technology useful for receivers, and more specifically to a latch circuit, a CDR circuit, and a receiver including these circuits.

### BACKGROUND OF THE INVENTION

Recently, an increasing number of devices are employing serial transfer methods for, transmitting and receiving data to and from other devices at a high speed. According to a typical approach, data synchronized to a clock signal is transmitted to a receiver over a transmission path, and the receiver extracts the clock signal from the received data for restoration thereof. Circuits that provide the function for extracting the clock signal from the received data are called CDR (Clock and Data Recovery) circuits. Data transmitted at a high transmission rate is first waveform-shaped using a waveform equalization technique and is then transferred to a CDR circuit. Waveform equalization techniques can be divided into two general categories: techniques using peaking amplifiers; and DFE (Decision Feedback Equalizer) in which sampled data is fed back. Typical DFE uses a method in which sampled data is fed back to an amplifier section in the preceding stage (see Japanese Unexamined Patent Application Publication No. 2005-341582).

### SUMMARY OF THE INVENTION

Because data transmitted to a receiver over a transmission path at a high transmission rate is attenuated and phase-shifted due to the frequency characteristics of the transmission path, the resultant attenuation and phase shift need to be corrected by a receiver circuit in the receiver. The receiver circuit corrects the attenuation and phase shift primarily by waveform equalization processing using multistage-connected amplifiers. However, the multistage connection of amplifiers leads to an increase in the power consumption of the receiver.

An object of the present invention is to provide a receiver that consumes less electric power.

According to one aspect of the present invention, there is provided a circuit that latches a differential signal by interrupting electric current generated by a differential input using a corresponding differential output when the differential signal is differentially amplified.

Using this latch circuit, transmitted data can be received even if the voltage difference between the differential signal components of the received signal is small. As a result, the number of amplifiers can be reduced, thereby enabling the power consumption of the receiver to be reduced.

### BRIEF DESCRIPTION OF THE DRAWINGS

FIG. 1 is a block diagram showing the overall configuration of a receiver according to a first embodiment of the invention;

FIG. 2 is a circuit diagram showing the configuration of a CCL (Cross Coupled Latch) circuit according to the first embodiment of the invention;

FIG. 3 is a diagram showing operation waveforms in the CCL circuit according to the first embodiment of the invention; and

FIG. 4 is a block diagram showing the overall configuration of a receiver according to a second embodiment of the invention.

### DETAILED DESCRIPTION OF THE PREFERRED EMBODIMENTS

The present invention will now be described in detail through embodiments thereof.

### First Embodiment

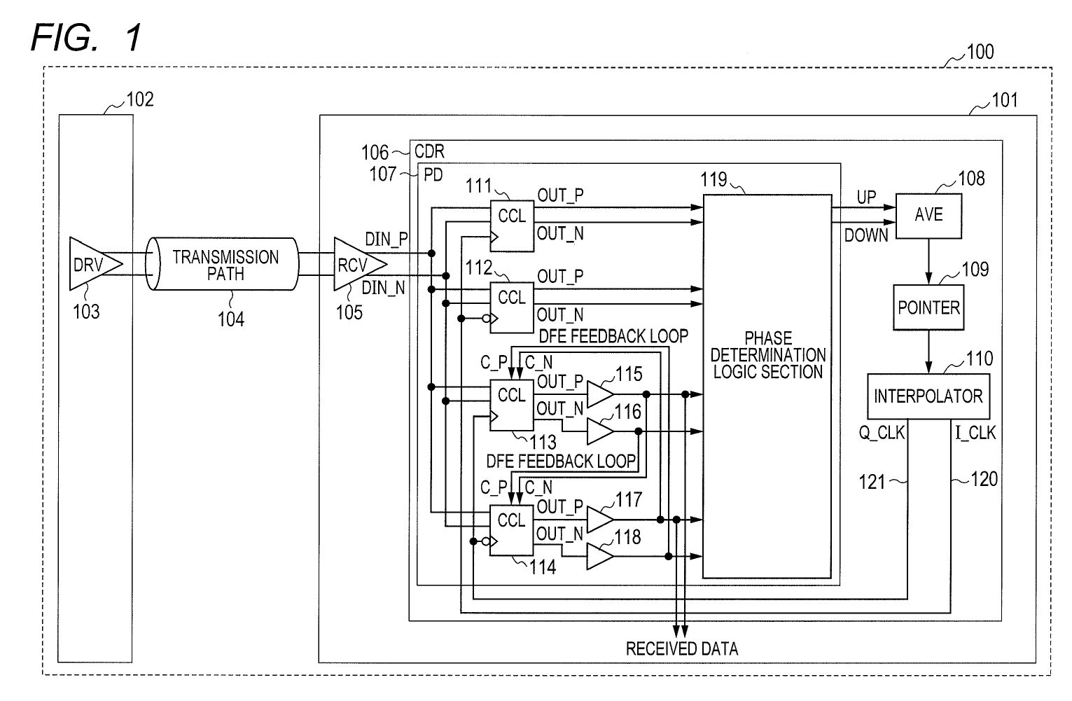

This embodiment provides an example in which the invention is applied to phase comparison between received data and a clock signal (recovered clock signal) extracted from the received data performed in a CDR circuit of a receiver. FIG. 1 shows a transmitting/receiving system 100 including a receiving circuit 101 according to the embodiment.

The receiving circuit 101 includes a receiver circuit 105 that receives as input the differential signal components of a transmitted serial signal that is outputted from a driver circuit 103 in a transmitting circuit 102 and that is transmitted over a transmission path 104, and a CDR circuit 106 that receives as input the output of the receiver circuit 105. The CDR circuit 106 includes a phase detector 107 that receives as input the output of the receiver circuit 105, an averaging circuit 108 that receives as input up- and down-signals from the phase detector 107, a pointer circuit 109 that receives as input the output of the averaging circuit 108, and an interpolator 110 that receives as input the output of the pointer circuit 109. The output of the interpolator 110 is inputted to the phase detector 107.

The CDR circuit 106 includes CCL (Cross Coupled Latch) circuits 111 to 114 having feedback inputs described below, delay elements 115 to 118 such as flip-flops, buffers, or the like, and a phase determination logic section 119. The CCL circuits 111 to 114 receives as input a differential signal that is outputted from the receiver circuit 105. The outputs of the CCL circuits 111 and 112 are inputted to the phase determination logic section 119. The differential outputs of the CCL circuit 113 are respectively input to the delay elements 115 and 116. The differential outputs of the CCL circuit 114 are respectively input into the delay elements 117 and 118. The outputs of the delay elements 115 and 116 are inputted to the feedback inputs of the CCL circuit 114 and to the phase determination logic section 119. The outputs of the delay elements 117 and 118 are inputted to the feedback inputs of the CCL circuit 113 and to the phase determination logic section 119.

The CDR circuit 106 according to the embodiment includes the CCL circuits 111 and 112 for latching an edge or its vicinity of the received data, and the CCL circuits 113 and 114 for latching the center or its vicinity of the received data. The reason why these CCL circuits, two of which are for latching the edge or its vicinity while the remaining two are for latching the center or its vicinity, are provided is that the CDR circuit 106 according to the embodiment operates at a half-rate; these CCL circuits are provided so that foreground data is latched by the CCL circuits 111 and 113 while background data is latched by the CCL circuits 112 and 114. Furthermore, because the CDR circuit 106 according to the invention operates at a half-rate and the output of the CCL circuit 113 that receives the foreground data is connected to the feedback inputs of the CCL circuit 114 via the delay elements 115 and 116 while the output of the CCL circuit 114 that receives the background data is connected to the feedback inputs of the CCL circuit 113 via the delay elements 117 and 118, the CDR circuit performs single-tap DFE (Decision Feedback Equalization) processing in which data in the preceding symbol period is reflected in data in the current symbol period. The DFE processing adjusts the minimum input amplitude limit with respect to the pattern of data as described below, thereby enhancing the reception performance of the CDR circuit. More specifically, when the received data transits from a high voltage state (HIGH) to a low voltage state (LOW) after it has been continuously received in the HIGH state or when the received data transits from LOW to HIGH after it has been continuously received in the LOW state, the amplitude that can be received is reduced. Therefore, the minimum input amplitude limit is adjusted so that it is reduced. It is to be noted that the feedback function described later is disabled with respect to the CCL circuits 111 and 112.

The phase determination logic section 119 calculates exclusive ORs of the signals output from the CCL circuits 111 and 112 and the delay elements 115 to 118 to detect the phase difference between the received data and recovered clock signal components 120 and 121, thereby outputting phase control signals, i.e., a phase-lead signal (down-signal) and a phase-lag signal (up-signal). The down-signal is generated by the exclusive OR of the output of the CCL circuit 111 and the output of the CCL circuit 113 and the exclusive OR of the output of the CCL circuit 112 and the output of the CCL circuit 114. The up-signal is generated by the exclusive OR of the output of the CCL circuit 112 and the output of the CCL circuit 113 and the exclusive OR of the output of the CCL circuit 111 and the output of the CCL circuit 114. When these exclusive ORs are generated, timing is adjusted using a flip-flop circuit or the like so that the logical operations are performed in a timely fashion. In this manner, detection is performed at four locations including the edge or its vicinity of the received foreground and background data and the center or its vicinity of the received foreground and background data, thereby outputting the phase-lead signal (down-signal) and the phase-lag signal (up-signal).

The averaging circuit 108 averages the signals output from the phase detector 107. The pointer circuit 109 controls the phases of the recovered clock signal components 120 and 121 on the basis of the signals output from the averaging circuit 108. The interpolator circuit 110 has a function for generating the recovered clock signal components 120 and 121 having phases specified by the signal output from the pointer circuit 109. It is to be noted that the recovered clock signal components 120 and 121 are 90 degrees out of phase with each other. More specifically, the recovered clock signal component 121 is 90 degrees delayed in phase with respect to the recovered clock signal component 120.

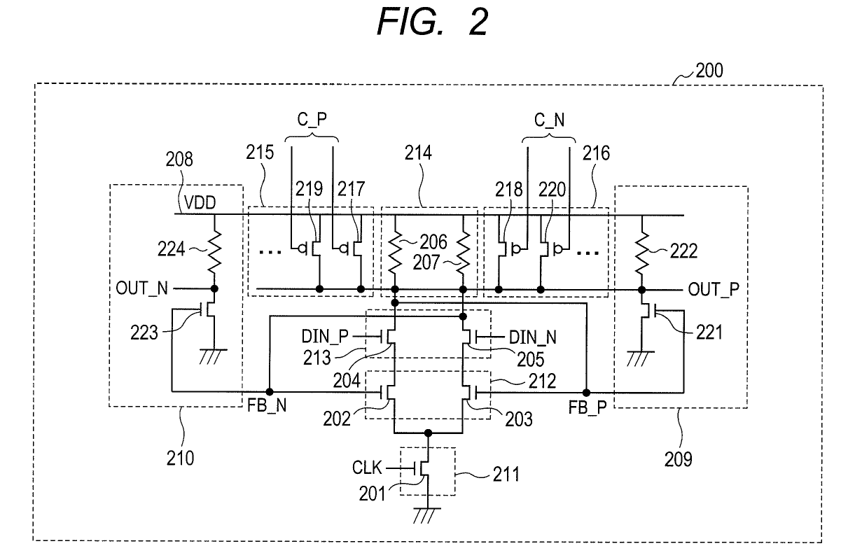

FIG. 2 shows a CCL circuit 200 that is an exemplary circuit capable of being used as the CCL circuits 111 to 114. The CCL circuit 200 includes a first MOS transistor 201 having the source connected to ground and the gate that receives as input a clock signal, a second MOS transistor 202 having the source connected to the drain of the first MOS transistor 201, a third MOS transistor 203 having the source connected to the drain of the first MOS transistor 201, a fourth MOS transistor 204 having the source connected to the drain of the second MOS transistor 202 and the drain connected to a power supply 208 via a resistor 206, and a fifth MOS transistor 205 having the source connected to the drain of the third MOS transistor 203 and the drain connected to the power supply 208 via a second resistor 207. The drain of the fourth MOS transistor 204 is connected to the gate of the third MOS transistor 203, and the drain of the fifth MOS transistor 205 is connected to the gate of the second transistor 202. In this embodiment, the clock signal input to the gate of the first MOS transistor 201 is either the recovered clock signal component 120 or the recovered clock signal component 121. It is to be noted that the MOS transistors 201 to 205 are N-type MOS transistors.

The CCL circuit 200 includes, as a portion thereof, a latch circuit in which the gate of the fourth MOS transistor 204 serves as a first input (DIN_P), the gate of the fifth MOS transistor 205 serves as a second input (DIN_N), the drain of the fourth MOS transistor 204 serves as a first output (FB_P), and the drain of the fifth MOS transistor 205 serves as a second output (FB_N). Furthermore, the CCL circuit 200 also includes a first inverter circuit 209 that receives as input the first output (FB_P) and a second inverter circuit 210 that receives as input the second output (FB_N), and the output (OUT_P) of the first inverter circuit 209 and the output (OUT_N) of the second inverter circuit 210 serve as the outputs of the CCL circuit 200. The first input (DIN_P) and the second input (DIN_N) also serve as the inputs of the CCL circuit 200, and receive as input the differential signal of the transmitted data output from the receiver circuit 105.

The portion of the CCL circuit 200 that constitutes the latch circuit includes a clock signal input section 211 that has the first MOS transistor 201 and that controls the turning on/off of circuit current on the basis of the clock signal, a current control section 212 that has the second MOS transistor 202 and the third MOS transistor 203 and that limits the circuit current on the basis of the output, a transmitted data input section 213 that has the fourth MOS transistor 204 and the fifth MOS transistor 205, and a resistor section 214 that has the first resistor 206 and the second resistor 207. The operation of the CCL circuit 200 as a latch circuit will now be described.

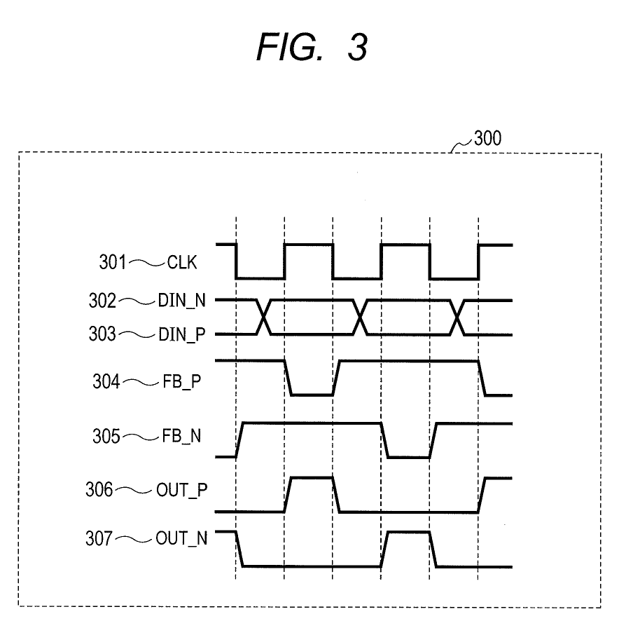

FIG. 3 shows operation waveforms 300 in the CCL circuit 200. The operation waveforms 300 schematically shows the waveform 301 of the clock signal, the waveform 303 that is inputted to the first input (DIN_P), the waveform 302 that is inputted to the second input (DIN_N), the waveform 304 that is outputted from the first output (FB_P), the waveform 305 that is outputted from the second output (FB_N), the waveform 306 of the output (OUT_P) of the first inverter circuit 209, and the waveform of the output (OUT_N) of the second inverter circuit 210.

When the clock signal goes high, the first MOS transistor 201 of the clock signal input section 211 turns on. Then, the voltages between the drain terminals and the source terminals of the cascode-connected MOS transistors start falling. As a result, one of the fourth MOS transistor 204 and the fifth MOS transistor 205 in the transmitted data input section 213, which serve as the first input and the second input, turns on depending on the differential voltage difference of the transmitted data input to the first input (DIN_P) and the second input (DIN_N). The drain voltage of the MOS transistor in the transmitted data input section 213 that has turned on, i.e., one of the first output (FB_P) and the second output (FB_N) the MOS transistor of which has turned on, is quickly pulled toward ground, and at the same time, one of the second MOS transistor 202 and the third MOS transistor 203 in the current control section 212 that has the gate connected to the drain of the MOS transistor that has turned on turns off. The drain voltage of the MOS transistor in the transmitted data input section 213 that is connected to the drain of one of the second MOS transistor 202 and the third MOS transistor 203 in the current control section 212 that has turned off is pulled toward the power supply voltage (VDD) of the power supply 208. Therefore, when the first input (DIN_P) has a higher input voltage than the second input (DIN_N), the second output (FB_N) and the first output (FB_P) are respectively latched HIGH and LOW, and when the second input (DIN_N) has a higher input voltage than the first input (DIN_P), the first output (FB_P) and the second output (FB_N) are respectively latched HIGH and LOW.

As a result, even if a differential signal having a small voltage difference is inputted from the first input (DIN_P) and the second input (DIN_N), latching can be accomplished, thereby allowing the corresponding signal to be extracted from the first output (FB_P) and the second output (FB_N). In other words, the CCL circuit 200 constitutes a sense amplifying latch circuit. In this manner, even a differential signal having only a small voltage difference can be detected with high sensitivity using a simple configuration if circuit current generated by a differential input is interrupted using a corresponding differential output to latch the differential signal when the differential signal is differentially amplified.

Therefore, using the CCL circuit 200 as the CCL circuits 111 to 114 in the CDR circuit 106, the CDR circuit 106 can detect transmitted data with high sensitivity. More specifically, the CDR circuit 106 can detect transmitted data with high sensitivity even from a signal that has been attenuated and phase-shifted by the transmission path because phase comparison for phase adjustment between the transmitted data, i.e., the received data, and the recovered clock signal can be performed with high sensitivity by the CCL circuits 111 to 114. Furthermore, because the CDR circuit 106 can detect transmitted data with high sensitivity, it is possible to reduce the number of amplifiers included in the receiver circuit 105 that precedes the CDR circuit 106, thereby enabling the power consumption of the receiving circuit 101 to be reduced.

The feedback input of the CCL circuit 200 will now be described. The CCL circuit 200 includes feedback input sections 215 and 216. The feedback input section 215 and the feedback input section 216 are respectively connected with the first resistor 206 and the second resistor 207 in parallel.

The feedback input section 215 includes a sixth MOS transistor 217 having the drain connected to the drain of the fourth MOS transistor 204 in the transmitted data input section 213 and the source connected to the power supply 208. The feedback signal component (C_P) shown in FIG. 1 is inputted to the gate of the sixth MOS transistor 217.

The feedback input section 216 includes a seventh MOS transistor 218 having the drain connected to the drain of the fifth MOS transistor 205 in the transmitted data input section 213 and the source connected to the power supply 208. The feedback signal component (C_N) shown in FIG. 1 is inputted to the gate of the seventh MOS transistor 218.

Although FIG. 2 shows an example in which the sixth MOS transistor 217 is further connected with a MOS transistor 219, etc. in parallel and the seventh MOS transistor 218 is further connected with a MOS transistor 220, etc. in parallel, the CCL circuit 200 need not necessarily include anything else other than the sixth MOS transistor 217 and the seventh MOS transistor 218. The responsiveness of the CCL circuit 200 to the feedback input can be adjusted by altering the number of the parallel connections. It is to be noted that the MOS transistors 217 to 220 are P-type MOS transistors.

The feedback input sections 215 and 216 operate to achieve the same result as the resistance of the resistor section 214 connected to the transmitted data input section 213 being reduced. For example, when the CCL circuit 200 is used in a single-tap DFE system, more specifically, for the CCL circuits 113 and 114 shown in FIG. 1, the resistance of the resistor section 214 is changed by turning on/off the MOS transistors that constitute the feedback input sections 215 and 216 on the basis of the transmitted signal in the preceding symbol period. Turning on/off the MOS transistors in the feedback input sections 215 and 216 using the feedback input components C_P and C_N causes electric currents flowing through the fourth MOS transistor 204 and the fifth MOS transistor 205 in the transmitted data input section 213 to differ from each other. As a result, it is possible to alter the time at which the fourth MOS transistor 204 and the fifth MOS transistor 205 in the transmitted data input section 213 are tuned on/off.

For example, when the transmitted signal input to the first input (DIN_P) in the preceding symbol period is a low voltage (LOW) signal, the resistance connected to the drain of the fifth MOS transistor 205 is reduced so that a high voltage (HIGH) signal can be easily received in the current symbol period. As a result, when a HIGH signal is inputted to the first input (DIN_P), i.e., the gate of the fourth MOS transistor 204, and a LOW signal is inputted to the second input (DIN_N), i.e., the gate of the fifth MOS transistor 205, the fourth MOS transistor 204 can easily turn on. On the other hand, when the transmitted data input to the first input (DIN_P) in the preceding symbol period is a HIGH signal, the resistance connected to the drain of the fourth MOS transistor 204 is reduced so that a LOW signal can be easily received in the current symbol period. As a result, when a LOW signal is inputted to the first input (DIN_P), the gate of the fourth MOS transistor 204, and a HIGH signal is inputted to the second input (DIN_N), i.e., the gate of the fifth MOS transistor 205, the fifth MOS transistor 205 can easily turn on. In this manner, the CCL circuit 200 changes the combined resistance of the resistor section 214 and the feedback input sections 215 and 216 on the basis of the pattern of transmitted data, thereby enabling the minimum input amplitude limit to be adjusted with respect to the data pattern.

By changing the combined resistance of the resistor section 214 and the feedback input sections 215 and 216 on the basis of transmitted data, even transmitted data that has been attenuated and phase-shifted by the transmission path 104 can be reliably received by the receiver 101. Furthermore, because the feedback paths for the DFE system are provided within the phase detector 107, more specifically, in the vicinity of the CCL circuits 113 and 114, the lengths of the loops are substantially reduced, when compared to cases in which the feedback paths are provided from the phase detector to other sections such as the receiver circuit in the preceding stage, thereby enabling high speed processing in the CDR circuit 106 and therefore in the receiving circuit 101 to be achieved.

### Second Embodiment

This embodiment provides an example in which the CCL circuit 200 shown in FIG. 2 is used in an eye monitor circuit that observes the state of received data. This eye monitor circuit offsets received data in phase and voltage to check the transmission data, thereby measuring the eye opening of the received data.

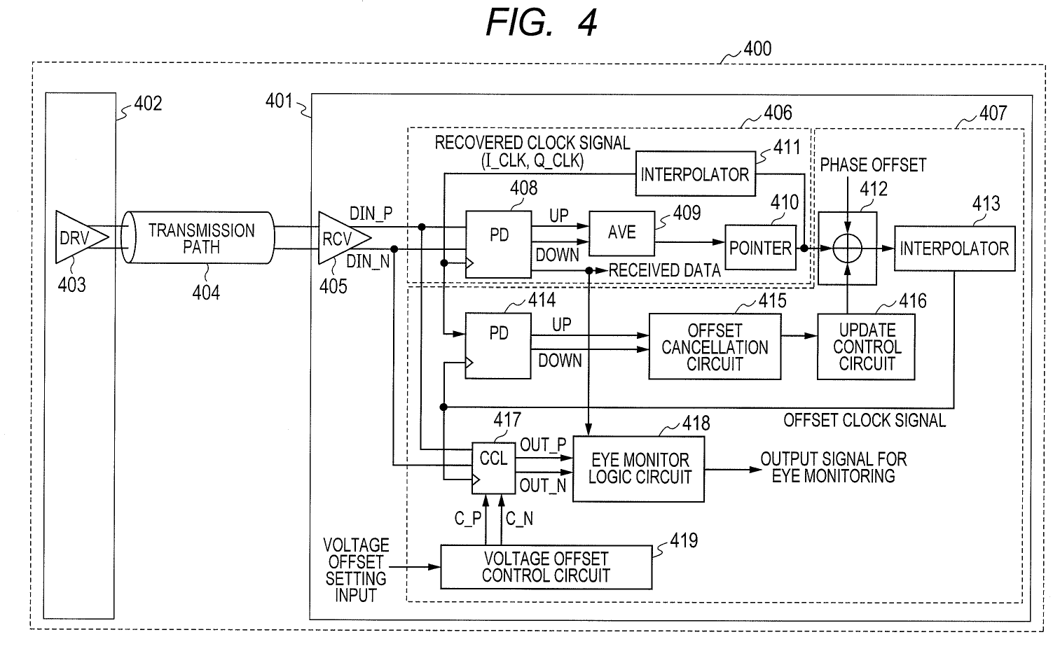

FIG. 4 shows an embodiment of a transmitting/receiving system 400 including a receiver 401 in which the CCL circuit 200 shown in FIG. 2 is used in an eye monitor. The receiver 401 shown in FIG. 4 includes a receiver circuit 405 that receives as input the differential signal components of a transmitted serial signal that is outputted from a driver circuit 403 in a transmitting circuit 402 and is transmitted over a transmission path 404, a CDR circuit 406 that receives as input the output of the receiver circuit 405, and an eye monitor circuit 407 that receives as input the output of the receiver circuit 405.

The CDR circuit 406 includes a phase detector 408, an averaging circuit 409, a pointer circuit 410, and an interpolator circuit 411. The phase detector 408, the averaging circuit 409, the pointer circuit 410, and the interpolator circuit 411 constitute a section of the CDR circuit 406 that performs phase adjustment between received data and a recovered clock signal.

The eye monitor circuit 407 includes a phase offset circuit 412, an interpolator circuit 413, a phase detector 414, an offset cancellation circuit 415, an update control circuit 416, a CCL (Cross-Coupled Latch) circuit 417 having feedback inputs, an eye monitor logic circuit 418, and a voltage offset control circuit 419. The CCL circuit 200 is used as the CCL circuit 417.

The voltage offset of the eye monitor circuit 407 is achieved by the CCL circuit 417, the eye monitor logic circuit 418, and the voltage offset control circuit 419. The CCL circuit 417 has the same configuration as shown in FIG. 2, and the feedback input sections 215 and 216 are controlled by the voltage offset control circuit 419.

When a voltage offset setting is inputted to the voltage offset control circuit 419 from outside and a voltage offset is set, the voltage offset control circuit 419 determines whether to turn on/off the MOS transistors in the feedback input sections 215 and 216 of the CCL circuit 417.

Because in the CCL circuit 417, the turning on/off of the MOS transistors in the feedback input sections 215 and 216 is set irrespective of the transmitted data from the receiver circuit 405, the minimum input amplitude limit for the CCL circuit 417 may be increased, i.e., latching may become difficult, depending on the pattern of the transmitted data. For example, when transmitted data that transits from LOW to HIGH is checked, the resistance connected to the drain of the fourth MOS transistor 204 in the transmitted data input section 214 is reduced, i.e., the combined resistance of the first resistor 206 and the feedback input section 215 is reduced. By reducing the combined resistance of the first resistor 206 and the feedback input section 215, it is difficult to receive data that transits from LOW to HIGH. More specifically, the minimum input amplitude limit for the transmitted data that transits from LOW to HIGH is increased. On the other hand, when transmitted data that transits from HIGH to LOW is checked, the resistance connected to the drain of the fifth transistor 205 in the transmitted data input section 213 is reduced, i.e., the combined resistance of the second resistor 207 and the feedback input section 216 is reduced. By reducing the combined resistance of the second resistor 207 and the feedback input section 216, it is difficult to receive data that transits from HIGH to LOW. More specifically, the minimum input amplitude limit for the transmitted data that transits from HIGH to LOW is increased. In this manner, the eye monitor 407 achieves its voltage offset function by selectively changing the minimum input amplitude limit on the basis of these data patterns.

The eye monitor circuit 407 uses the eye monitor logic circuit 418 to process the transmitted data received by applying the voltage offset controlled from outside via the voltage offset control circuit 419 and the received data that has been received by the phase detector 408 and to which no voltage offset has been applied, thereby measuring the waveform of the received data. By processing the output signal of the eye monitor logic circuit 418 using software or the like, the waveform of the transmitted data can be plotted on a two dimensional plane or the like.

The phase offset of the eye monitor circuit 407 is achieved by the phase detector 408, the averaging circuit 409, the pointer circuit 410, and the interpolator circuit 411 in the CDR circuit 406, and the phase offset circuit 412 and the interpolator circuit 413. By adjusting the phases of the received data and the recovered clock signal components (I_CLK and Q_CLK) in the phase adjustment circuit section of the CDR circuit 406 and adding a phase offset from outside to the phase of the recovered clock signal in the phase offset circuit 412, an offset clock signal having an arbitrary phase offset with respect to the recovered clock signal locked to the received data can be generated.

Because the present embodiment is an eye monitor circuit that operates at a half-rate, accurate measurement of the eye pattern cannot be performed if there is a phase difference between the recovered clock signal and the offset clock signal with no phase offset from outside applied. In order to cancel the phase difference between the recovered clock signal generated in the CDR circuit 406 and the offset clock signal with no phase offset from outside applied, a circuit is used that includes the phase detector 414, the offset cancellation circuit 415, and the update control circuit 416.

The phase detector 414 detects the phase difference between the recovered clock signal and the offset clock signal. The offset cancellation circuit 415 averages this phase difference information and calculates the amount of offset, and the update control circuit 416 controls the time at which the offset clock signal is updated using the offset cancellation information. By cancelling the phase difference between the recovered clock signal and the offset clock signal with no phase offset applied, a correct amount of offset can be set for the recovered clock signal that tracks the received data, thereby enabling the eye pattern of the received data to be accurately measured.

The present invention is not limited to the above embodiments, and modifications may be made without departing from the scope of the present invention.

What is claimed is:

1. A latch circuit, comprising:
a first MOS transistor having a source connected to ground and a gate that receives as input a clock signal;
a second MOS transistor having a source connected to a drain of the first MOS transistor;
a third MOS transistor having a source connected to the drain of the first MOS transistor;
a fourth MOS transistor having a source connected to a drain of the second MOS transistor and a drain connected to a power supply via a first resistor; and
a fifth MOS transistor having a source connected to a drain of the third MOS transistor and a drain connected to the power supply via a second resistor,
wherein the drain of the fourth MOS transistor is connected to a gate of the third MOS transistor,
wherein the drain of the fifth MOS transistor is connected to a gate of the second MOS transistor,
wherein a gate of the fourth MOS transistor serves as a first input,
wherein a gate of the fifth MOS transistor serves as a second input,
wherein the drain of the fourth MOS transistor serves as a first output, and
wherein the drain of the fifth MOS transistor serves as a second output.

2. The latch circuit according to claim 1, further comprising:
a sixth MOS transistor having a drain connected to the drain of the fourth MOS transistor and a source connected to the power supply; and
a seventh MOS transistor having a drain connected to the drain of the fifth MOS transistor and a source connected to the power supply.

3. The latch circuit according to claim 1,
wherein a differential signal is inputted to the first input and the second input.

4. The latch circuit according to claim 1,
wherein an output signal from the first output is inputted to a first inverter circuit, and
wherein an output signal from the second output is inputted to a second inverter circuit.

5. A CDR circuit comprising:
the latch circuit according to claim 1,
wherein received data is inputted to the first and second inputs, and
wherein phase adjustment between the received data and an externally introduced clock signal is made according to an output signal from the first and second outputs.

6. A receiving circuit comprising the CDR circuit according to claim 5.

7. A receiver comprising the latch circuit according to claim 1,
wherein received data is inputted to the first and second inputs, and
wherein a waveform of the received data is measured according to an output signal from the first and second outputs.

8. A latch circuit comprising a differential amplifying circuit,
wherein an electric current generated in the differential amplifying circuit by a differential input to the differential amplifying circuit is interrupted using corresponding differential output from the differential amplifying circuit.

9. A CDR circuit comprising the latch circuit according to claim 8,
wherein received data is inputted to the differential amplifying circuit, and
wherein phase adjustment between the received data and an externally introduced clock signal is made according to an output from the differential amplifying circuit.

10. A receiving circuit comprising the CDR circuit according to claim 9.
